(19) United States
(12) Patent Application Publication
(10) Pub. No.: US 2025/0369868 A1
(43) Pub. Date: Dec. 4, 2025

(54) ENVIRONMENTAL CONDITIONING DEVICE, PROCESSING SYSTEM, ARTICLE MANUFACTURING METHOD, AND MANAGEMENT METHOD

(71) Applicant: CANON KABUSHIKI KAISHA, Tokyo (JP)

(72) Inventor: SHINTARO AICHI, Tochigi (JP)

(21) Appl. No.: 19/216,081

(22) Filed: May 22, 2025

(30) Foreign Application Priority Data
May 28, 2024 (JP) 2024-086460

(51) Int. Cl. G01N 17/00; B01D 46/00; G01G 19/00

(52) U.S. Cl. CPC G01N 17/002; G01G 19/00; B01D 46/0086

(57) ABSTRACT

An environmental conditioning device includes a containment vessel configured to store a filter element and including a primary side space and a secondary side space separated by the filter element, a measuring instrument configured to measure a weight of the containment vessel, a first flexible duct connected to an inlet of the primary side space, and a second flexible duct connected to an outlet of the secondary side space.

### BACKGROUND

### Field of the Technology

The present disclosure relates to an environmental conditioning device, a processing system, an article manufacturing method, and a management method.

### Description of the Related Art

Japanese Patent Laid-Open No. 2014-42911 describes a filter device in which a filter element is provided in each hole of a perforated plate arranged in the filter device. This filter device includes a weight sensor that measures the weight of the filter element, and sets a parameter for cleaning the filter element based on an output of the weight sensor.

In a configuration described in Japanese Patent Laid-Open No. 2014-42911, the filter element needs to be supported in such form that the weight of the filter element can be measured. For example, in a case where the filter element is fixed to a structure that supports the filter element, it is impossible to measure the weight of the filter element.

### SUMMARY

The present disclosure provides a technique advantageous in monitoring the state of a filter element.

One of aspects of the present disclosure provides an environmental conditioning device comprising: a containment vessel configured to store a filter element and including a primary side space and a secondary side space separated by the filter element; a measuring instrument configured to measure a weight of the containment vessel; a first flexible duct connected to an inlet of the primary side space; and a second flexible duct connected to an outlet of the secondary side space.

### BRIEF DESCRIPTION OF THE DRAWINGS

FIG. 1 is a view schematically showing the configuration of a processing system according to an embodiment;

FIG. 2 is a view schematically showing a first configuration example of an environmental conditioning device or a filtering device;

FIG. 3 is a view schematically showing a second configuration example of the environmental conditioning device or the filtering device;

FIG. 4 is a view schematically showing a third configuration example of the environmental conditioning device or the filtering device; and

FIG. 5 is a flowchart illustrating the procedure of a management method of managing the environmental conditioning device.

Further features of the disclosure will become apparent from the following description of exemplary embodiments with reference to the attached drawings.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

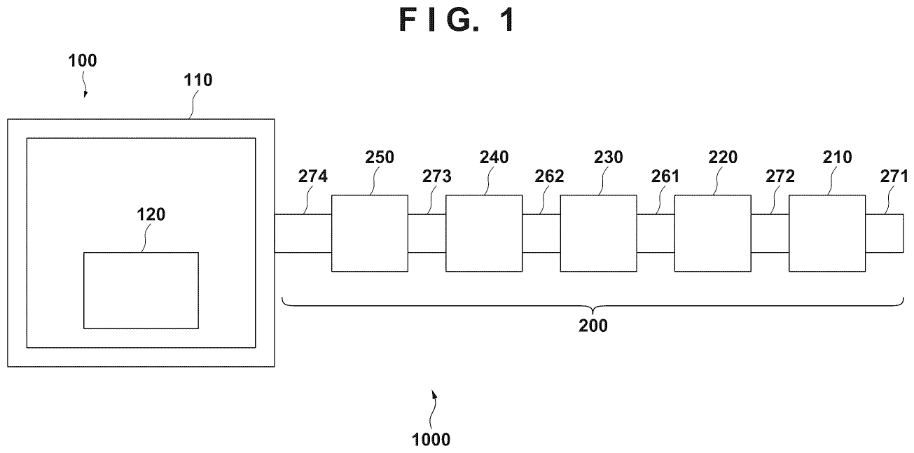

FIG. 1 schematically shows the configuration of a processing system 1000 according to an embodiment. The processing system 1000 can include a processing device 100 and an environmental conditioning device 200. The processing device 100 can include a chamber 110 and a processing unit 120 that performs processing in the chamber 110. The environmental conditioning device 200 conditions an environment in the chamber 110 of the processing device 100. The chamber 110 is a component for surrounding a space, and, for example, may be arranged in a clean room or may be a clean room. The meaning of the term “processing” is widely interpreted, and includes, for example, adding a physical element to a processing target object, deleting a physical element from a processing target object, changing the properties of the whole or a part of a processing target object, and giving energy to a processing target object. Furthermore, the meaning of the term “processing” includes measuring, inspecting, and observing a processing target object. The processing unit 120 is configured to, for example, perform processing of transferring a pattern of an original to a processing target object. In this case, the processing device 100 is a transfer device that transfers a pattern of an original to a processing target object, for example, an exposure device or an imprint device. Note that the exposure device forms a latent image on a photosensitive material of a substrate as a processing target object, and the imprint device adds a film having a pattern to a substrate as a processing target object.

The environmental conditioning device 200 can include, for example, a filtering device 230. The environmental conditioning device 200 may further include, for example, a cooler 220 and a heater 240. The cooler 220 can be configured to cool air to a first target temperature and supply cooled air to the filtering device 230. The heater 240 can be configured to receive air filtered by the filtering device 230, heat air to a second target temperature, and send it. The filtering device 230 and the cooler 220 can be connected by a first flexible duct 261. The filtering device 230 and the heater 240 can be connected by a second flexible duct 262. The term “flexible duct” is used as, for example, a term including a bellows, a base isolation duct, and a duct having a labyrinth structure.

The environmental conditioning device 200 may further include a blower 210 that supplies air to the cooler 220. The blower 210 can be configured to, for example, take air from a duct 271 and send it to the cooler 220 via a duct 272. The blower 210 may be arranged at an arbitrary position between the cooler 220 and the processing device 100. The environmental conditioning device 200 may further include a particle collection filter 250. The particle collection filter 250 can be arranged, for example, between the heater 240 and the processing device 100. The particle collection filter 250 and the heater 240 can be connected by a duct 273, and the particle collection filter 250 and the processing device 100 can be connected by a duct 274.

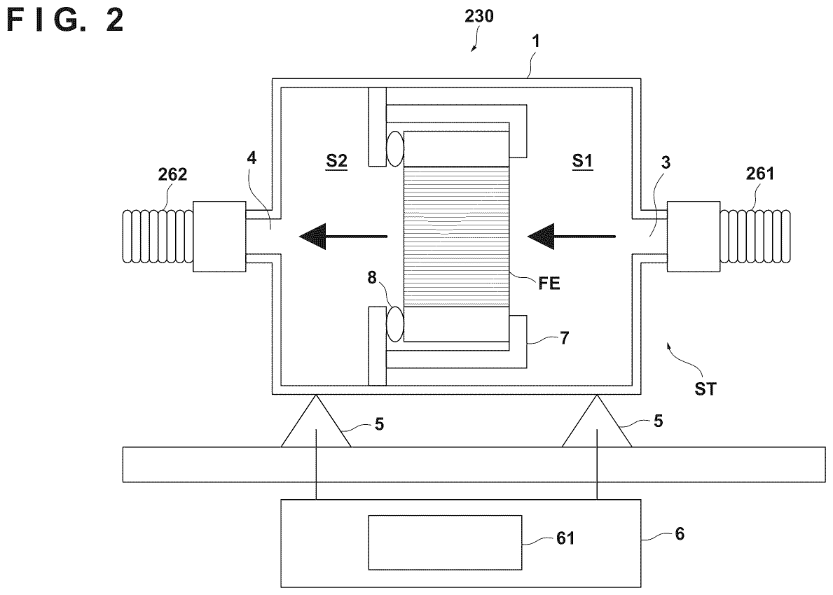

FIG. 2 schematically shows a first configuration example of the environmental conditioning device 200 or the filtering device 230. The environmental conditioning device 200 or the filtering device 230 can include a containment vessel 1, a measuring instrument 5, the first flexible duct 261, and the second flexible duct 262. The containment vessel 1 can store a filter element FE, and form a primary side space S1 and a secondary side space S2 separated by the filter element FE. From another viewpoint, the containment vessel 1 stores the filter element FE, and includes the primary side space S1 and the secondary side space S2 separated by the filter element FE. The containment vessel 1 can include a support 7 that supports the filter element FE. The filter element FE can be, for example, a chemical filter element. For example, the support 7 can support the filter element FE by pressing a seal member 8 against the filter element FE. The measuring instrument 5 can be configured to measure the weight of the containment vessel 1 storing the filter element FE. The measuring instrument 5 can include one or a plurality of weight scales. The containment vessel 1 includes an inlet 3 communicating with the primary side space S1, and an outlet 4 communicating with the secondary side space S2. The first flexible duct 261 is connected to the inlet 3 of the primary side space S1, and the second flexible duct 262 is connected to the outlet 4 of the secondary side space S2.

The environmental conditioning device 200 or the filtering device 230 may further include a controller 6. The controller 6 can include an output unit 61 that outputs state information representing the state of the filter element FE based on an output of the measuring instrument 5. Note that the output unit 61 may be provided separately from the controller 6. The output unit 61 includes, for example, an output device such as a display device (a display, a light emitting element, or the like), a loudspeaker, or a network interface, and can output state information using the output device. The controller 6 can be formed by, for example, a PLD (the abbreviation of Programmable Logic Device) such as an FPGA (the abbreviation of Field Programmable Gate Array), an ASIC (the abbreviation of Application Specific Integrated Circuit), a general-purpose or dedicated computer incorporating a program, or a combination of some or all of these.

The controller 6 or the output unit 61 can be configured to output state information representing the state of the filter element FE based on an output of the measuring instrument 5 in a state in which filtering by the filter element FE is performed. The controller 6 or the output unit 61 can be configured to, for example, output state information representing the state of the filter element FE based on a change in output of the measuring instrument 5. The state information representing the state of the filter element FE can include, for example, information concerning the remaining life of the filter element FE. The information concerning the remaining life of the filter element FE may be, for example, information representing the remaining usable period or information representing the degree of degradation of the filter element FE. The controller 6 or the output unit 61 may output state information representing the state of the filter element FE based on humidity in addition to the output of the measuring instrument 5.

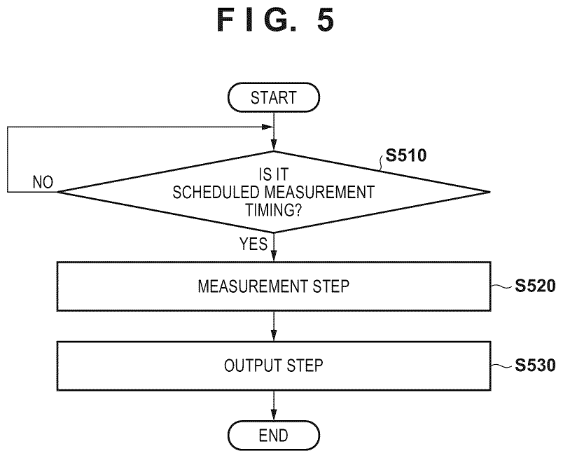

In one aspect, the controller 6 executes a management method of managing the environmental conditioning device 200. FIG. 5 exemplifies the management method of the environmental conditioning device 200 executed by the controller 6. The management method can include a measurement step S520 of measuring the weight of the containment vessel 1 storing the filter element FE and an output step S530 of outputting state information representing the state of the filter element FE based on the weight measured in the measurement step S520. The management method may include, for example, a determination step S510 of determining whether a scheduled measurement timing comes, and when the scheduled measurement timing comes, the measurement step S520 and the output step S530 can be executed. The measurement step S520 and the output step S530 may be executed by an interrupt using a timer instead of the determination step S510.

The environmental conditioning device 200 or the filtering device 230 may include a hygrometer in order to measure or acquire humidity, or may include an input interface used by a user or the like to input humidity.

A weight W_{wet} of water contained in a structure ST including the filter element FE and the containment vessel 1 can be given by a function of humidity m, that is, W_{wet}=W(m). The function W_{wet}=W(m) can be obtained in advance by an experiment or the like and incorporated in the controller 6.

When mₐ represents humidity, Wₐ represents the weight measurement value of the structure ST by the measuring instrument 5, and W_{drya} represents the dry weight of the structure ST on a use start date a of the filter element FE, it is possible to obtain:

$${W}_{drya} = {W}_{a} - W ( {m}_{a} ) \qquad ( 1 )$$

When m_{b} represents humidity and W_{b} represents the weight measurement value of the structure ST on a use date b of the filter element FE, a collected amount (mass) Wᵣ of a removal target object (for example, a chemical component) by the filter element FE on the use date b is given by:

$$\begin{matrix}{W}_{r} = {W}_{b} - W ( {m}_{b} ) - {W}_{drya} \\ = {W}_{b} - {W}_{a} - W ( {m}_{b} ) + W ( {m}_{a} )\end{matrix} \qquad ( 2 )$$

Normally, the containment vessel 1 does not absorb water. Therefore, normally, W(mₐ) represents the weight of water contained in the filter element FE on the use start date a, and W(m_{b}) represents the weight of water contained in the filter element FE on the use date b. When W_{cap} represents the collectable amount (mass) of the removal target object (for example, a chemical component) by the unused filter element FE (on the use start date b), and Wₑ₁ represents a remaining collectable amount (mass),

$${W}_{el} = {W}_{cap} - {W}_{r} \qquad ( 3 )$$

The remaining collectable amount may be understood as a remaining removable amount. The controller 6 may output, as state information or information representing the remaining life, for example, a value such as Wₑ₁, Wₑ₁/W_{cap}, or (W_{cap}−Wₑ₁)/W_{cap}, or information such as a bar graph or color obtained by converting the value.

In a case where the environmental conditioning device 200 is used under an environment or condition in which the humidity of air supplied to the filtering device 230 is regarded to be constant, it is unnecessary to consider the humidity, and Wᵣ=W_{b}−Wₐ holds.

In a case where the weight of the containment vessel 1 is regarded to remain unchanged, the collected amount (mass) Wᵣ of the removal target object (for example, a chemical component) by the filter element FE at an arbitrary date/time may be calculated by:

$${W}_{r} = Wmeas - {W}_{0} - {W}_{d} - Wf ( m ) \qquad ( 4 )$$

Where Wmeas represents the weight measurement value of the structure ST by the measuring instrument 5 at the arbitrary date/time, W₀ represents the weight of the containment vessel, Wₐ represents the dry weight of the filter element FE, and Wf(m) represents the weight of water contained in the filter element FE. Wf(m) can be obtained in advance as the function of the humidity m by an experiment or the like and incorporated in the controller 6. In this case as well, the controller 6 can calculate the remaining correctable amount (mass) Wₑ₁ at the arbitrary date/time by:

$${W}_{el} = {W}_{cap} - {W}_{r} \qquad ( 5 )$$

In a case where the filter element FE is a chemical filter element that removes (collects) organic gas, activated carbon is generally used as a filter material, and the collectable amount (mass) is generally about 5% to 10% of the weight of the filter element FE. For example, if a chemical filter element of 10 kg is used, the collectable amount is 500 to 1,000 g. Accordingly, the measurement resolution of the measuring instrument 5 is sufficiently, for example, 0.1 g.

The filter element FE can be formed by, for example, stacking a plurality of organic gas filter materials. The filter element FE can preferably collect only one of organic gas and inorganic gas. This is because, in general, a filter material that collects organic gas increases in weight by collection and a filter material that collects inorganic gas increases in weight by collection.

The first flexible duct 261 and the second flexible duct 262 can be configured such that influence on the measurement result of the structure ST by the measuring instrument 5 is negligible.

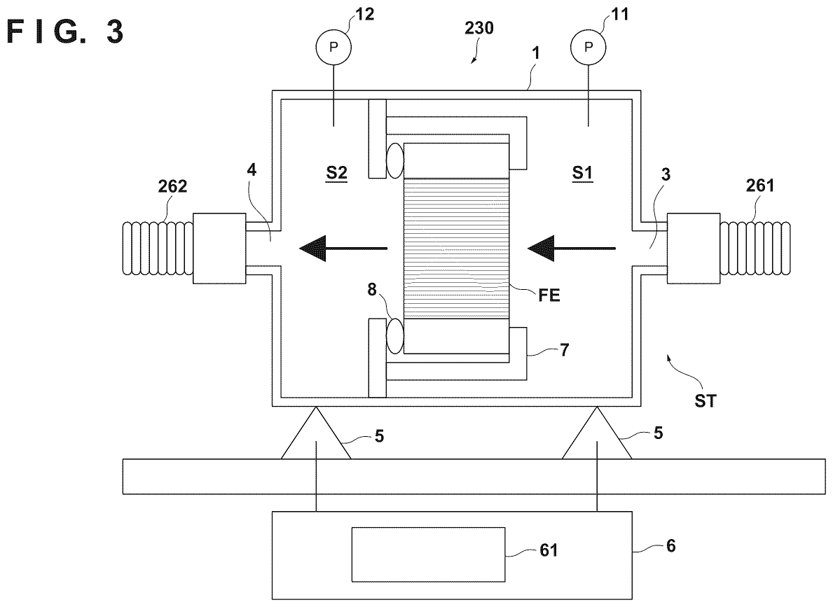

FIG. 3 schematically shows a second configuration example of the environmental conditioning device 200 or the filtering device 230. The second configuration example can be a configuration obtained by adding a first pressure gauge 11 and a second pressure gauge 12 to the first configuration example. The first pressure gauge 11 is arranged to measure the pressure in the primary side space S1, the second pressure gauge 12 is arranged to measure the pressure in the secondary side space S2, and outputs from the first pressure gauge 11 and the second pressure gauge 12 are provided to the controller 6. The controller 6 or the output unit 61 outputs state information representing the state of the filter element FE, for example, information concerning the remaining life based on the pressure in the primary side space S1 and the pressure in the secondary side space S2 in addition to the output of the measuring instrument 5.

A practical example will be described below. For example, P₀ represents the pressure in the containment vessel 1 before the filter element FE is mounted. In this state, since the containment vessel 1 is not separated into the primary side space S1 and the secondary side space S2 by the filter element FE, the output of the first pressure gauge 11 matches the output of the second pressure gauge 12. In the environmental conditioning device 200 in which the filter element FE is mounted and which is in an operating state, P₁ represents a pressure P in the primary side space S1 and P₂ represents a pressure P in the secondary side space S2. In addition, V₁ represents the volume of the primary side space S1 and V₂ represents the volume of the secondary side space S2. D₀, D₁, and D₂ represent densities D of air under the pressures P=P₀, P₁, and P₂, respectively. The density D can be calculated from the pressure P, and the relationship between the pressure P and the density D can be expressed by a function D=f(P).

In a case where the pressure P₁ in the primary side space S1 and the pressure P₂ in the secondary side space S2 are considered in the environmental conditioning device 200 in the operating state, the weight measurement values Wₐ and W_{b} by the measuring instrument 5 can be corrected by Wₐ as described below. That is, Wₐ-Wₐ is used as Wₐ, and W_{b}-Wₐ is used as W_{b}. Note that values at the time of obtaining the weight measurement values Wₐ and W_{b} are used as D₁ and D₂.

$${W}_{d} = ( {V}_{1} \times {D}_{1} + {V}_{2} \times {D}_{2} ) - ( {V}_{1} + {V}_{2} ) \times {D}_{0} \qquad ( 6 )$$

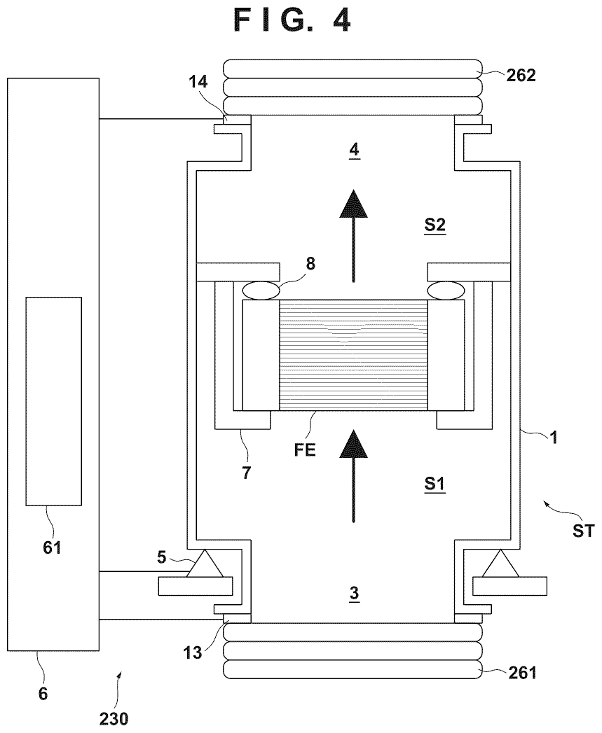

FIG. 4 schematically shows a third configuration example of the environmental conditioning device 200 or the filtering device 230. The third configuration example can be a configuration obtained by adding a first load cell 13 and a second load cell 14 to the first configuration example. The first load cell 13 is arranged between the first flexible duct 261 and the inlet 3 of the primary side space S1, and the second load cell 14 is arranged between the second flexible duct 262 and the outlet 4 of the secondary side space S2. Outputs from the first load cell 13 and the second load cell 14 are provided to the controller 6. Then, the controller 6 or the output unit 61 outputs state information representing the state of the filter element FE, for example, information concerning the remaining life based on the output of the first load cell 13 and the output of the second load cell 14 in addition to the output of the measuring instrument 5.

There is a case where the first flexible duct 261 and the second flexible duct 262 have non-negligible influence on the measurement value by the measuring instrument 5. For example, in the configuration shown in FIG. 4, the first flexible duct 261 and the second flexible duct 262 can function to offset a part of the gravity acting on the structure ST or to apply a force other than the gravity to the structure ST. When W₁ represents a force in the compression direction measured by the first load cell 13, and W₂ represents a force in the compression direction measured by the second load cell 14, Wₐ+W₁−W₂ can be used as Wₐ, and W_{b}+W₁−W₂ can be used as W_{b}. Note that values at the time of obtaining the weight measurement values Wₐ and W_{b} are used as W₁ and W₂.

In the processing system 1000, the processing unit 120 or the processing device 100 is configured to, for example, transfer a pattern of an original to a substrate, and the processing system 1000 can be used to perform an article manufacturing method of manufacturing an article. The article manufacturing method can include a transfer step of transferring a pattern of an original to a substrate by the processing system 1000, and a processing step of processing the substrate having undergone the transfer step to obtain an article. The processing step can include, for example, an etching step, a film forming step, a dicing step, and a sealing step. The article can be, for example, a semiconductor device, a display device, a MEMS, or the like.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-086460, filed May 28, 2024 which is hereby incorporated by reference herein in its entirety.

What is claimed is:

1. An environmental conditioning device comprising:
a containment vessel configured to store a filter element and including a primary side space and a secondary side space separated by the filter element;
a measuring instrument configured to measure a weight of the containment vessel;
a first flexible duct connected to an inlet of the primary side space; and
a second flexible duct connected to an outlet of the secondary side space.

2. The device according to claim 1, further comprising:
an output unit configured to output state information representing a state of the filter element based on an output of the measuring instrument.

3. The device according to claim 2, wherein
the output unit outputs the state information based on the output of the measuring instrument in a state in which filtering by the filter element is performed.

4. The device according to claim 3, wherein
the output unit outputs the state information based on a change in output of the measuring instrument.

5. The device according to claim 2, wherein
the output unit outputs, as the state information, information concerning a life of the filter element.

6. The device according to claim 2, wherein
the output unit outputs the state information based on humidity.

7. The device according to claim 2, wherein
the output unit outputs the state information based on a pressure in the primary side space and a pressure in the secondary side space.

8. The device according to claim 2, further comprising:
a first load cell arranged between the inlet and the first flexible duct; and
a second load cell arranged between the outlet and the second flexible duct,
wherein the output unit outputs the state information based on an output of the first load cell and an output of the second load cell in addition to the output of the measuring instrument.

9. The device according to claim 1, wherein
the filter element is a chemical filter element.

10. The device according to claim 9, wherein
the chemical filter element can collect only one of organic gas and inorganic gas.

11. The device according to claim 1, further comprising:
a cooler,
wherein the cooler and the inlet of the containment vessel are connected via the first flexible duct.

12. The device according to claim 11, further comprising:
a heater,
wherein the heater and the outlet of the containment vessel are connected via the second flexible duct.

13. A processing system comprising:
a processing device including a chamber and a processing unit configured to perform processing in the chamber; and
an environmental conditioning device configured to condition an environment in the chamber,
wherein the environmental conditioning device comprises:
a containment vessel configured to store a filter element and including a primary side space and a secondary side space separated by the filter element;
a measuring instrument configured to measure a weight of the containment vessel;
a first flexible duct connected to an inlet of the primary side space; and
a second flexible duct connected to an outlet of the secondary side space.

14. The system according to claim 13, wherein
the processing unit is configured to transfer a pattern of an original to a substrate.

15. An article manufacturing method comprising:
transferring a pattern of an original to a substrate by a processing system defined in claim 14; and
processing the substrate having undergone the transferring to obtain an article.

16. A management method of managing an environmental conditioning device which includes a containment vessel configured to store a filter element and including a primary side space and a secondary side space separated by the filter element and in which a first flexible duct is connected to an inlet of the primary side space and a second flexible duct is connected to an outlet of the secondary side space, the method comprising:
measuring a weight of the containment vessel storing the filter element; and
outputting state information representing a state of the filter element based on the weight measured in the measuring.
